(19) United States
(12) Patent Application Publication
(10) Pub. No.: US 2007/0229869 A1
(43) Pub. Date: Oct. 4, 2007

(54) Image processing apparatus, image processing method, and program

(75) Inventors: Itaru Furukawa, Kyoto (JP); Hiroyuki Segawa, Kyoto (JP)

Correspondence Address: MCDERMOTT WILL & EMERY LLP, 600 13TH STREET, N.W., WASHINGTON, DC, 20005-3096, US

(73) Assignee: DAINIPPON SCREEN MFG. CO., LTD.

(21) Appl. No.: 11/727,094

(22) Filed: Mar. 23, 2007

(30) Foreign Application Priority Data
Mar. 28, 2006 (JP) JP2006-087374

(51) Int. Cl. G03F 3/08

(52) U.S. Cl. 358/1.9; 358/518

(57) ABSTRACT

An image processing apparatus of the present invention compares a first proof image and a second proof image, to detect a different portion, and displays the different portion on a display part. Therefore, an operator can check the second proof image after subjected to an automatic trap processing in respect to only the different portion between the first proof image and the second proof image, and perform a trap edit processing as needed. Hence, the trap edit processing to the second proof image can be performed efficiently, and the operator's workload can be reduced.

### BACKGROUND OF THE INVENTION

1. Field of the Invention

The present invention relates to an image processing apparatus, an image processing method, and a program, which are adapted to perform an image processing including a trap processing with respect to an image for a multicolor printing.

2. Description of the Background Art

A printed matter of multicolor printing can be produced by printing images in sequence on a printing paper through printing plates made for respective color components (for example, the printing plates of C (cyan), M (magenta), Y (yellow), and K (black)). Therefore, a slight misregistration in the printing position of each printing plate might result in the disadvantage of causing spacing at the boundary portions of the respective colors in the image. In the process of making the printing plates, a trap processing of placing a boundary figure at a boundary portion of each color in an inputted image is performed to prevent the above-mentioned disadvantage.

When performing the trap processing, there is firstly performed an automatic trap processing of placing a boundary figure created based on certain parameters to the whole of the inputted image. Then, a trap edit processing is performed in which an operator visually checks and individually corrects portions not subjected to the optimum trap processing in the automatic trap processing.

However, in the process of making the printing plates, after the termination of the automatic trap processing and the trap edit processing to the initially inputted image (a first proof image), a corrected image (a second proof image) might be inputted. To the inputted second proof image, the automatic trap processing and the trap edit processing are performed in the same manner as in the first proof image. The operator therefore has to handle the trap edit processing to the second proof image by using substantially the same time and labor as in the first proof image. This is poor in working efficiency.

### SUMMARY OF THE INVENTION

The present invention is directed to an image processing apparatus performing an image processing including a trap processing with respect to an image for a multicolor printing.

According to an embodiment of the present invention, there is provided an image processing apparatus including: an image input part to input an image; an automatic trap processing part to perform an automatic trap processing based on a predetermined condition in respect to an inputted image; a trap edit processing accepting part to accept a trap edit processing in which each image after being subjected to the automatic trap processing is individually corrected by an operator; a compare check part to compare and detect, when a first proof image and a second proof image are inputted to the image input part, a different portion between the first proof image and the second proof image; and a display part to display the different portion. The trap edit processing accepting part accepts a trap edit processing to the second proof image in respect to the different portion displayed on the display part.

The operator can verify the second proof image after being subjected to the automatic trap processing, in respect to only the different portion between the first proof image and the second proof image, and perform the trap edit processing as needed. It is therefore capable of efficiently performing the trap edit processing to the second proof image, and reducing the operator's workload.

Preferably, the image processing apparatus further includes a check image creating part to create a check image based on an inputted image, and the compare check part compares a first check image created based on the first proof image and a second check image created based on the second proof image, to detect a different portion.

The different portion can be detected appropriately based on the image suitable for the compare check processing.

Preferably, the image processing apparatus further includes a preserving part to preserve contents of the trap edit processing.

The contents of the executed trap edit processing can be referred to as needed.

Preferably, the image processing apparatus further includes an applying part to apply the contents of the trap edit processing to the first proof image preserved in the preserving part, to the second proof image.

This further reduces the operator's workload in the trap edit processing to the second proof image. Further, the trap edit processing to the first proof image can be surely applied to the second proof image.

Preferably, the image processing apparatus further includes a specifying part to specify a portion where the trap edit processing to the first proof image is performed, and where the first proof image and the second proof image are common to each other.

It is capable of distinguishing portions where the history of the trap edit processing to the first proof image can be applied directly to the second proof image.

The present invention is also directed to an image processing method of performing an image processing including a trap processing to an image for a multicolor printing.

The present invention is also directed to a program stored in a storage medium to be executed by a computer.

Consequently, an object of the present invention is to provide an image processing apparatus, an image processing method, and a program, which are adapted to perform efficiently the trap edit processing to the second proof image.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing a plate making system including an image processing apparatus according to a preferred embodiment of the present invention;

FIG. 2 is a flow chart showing the flow of an image processing to a first proof image;

FIG. 3 is a flow chart showing the flow of an image processing to a second proof image;

FIG. 4 is a flow chart showing the flow of an RIP processing and an output processing;

FIG. 5 is a diagram showing the contents of a processing to the second proof image after being subjected to an automatic trap processing;

FIG. 6 is a diagram showing an example of a first proof image when it is inputted;

FIG. 7 is a diagram showing an example of the first proof image after being subjected to an automatic trap processing;

FIG. 8 is a diagram showing an example of the first proof image after being subjected to a trap edit processing;

FIG. 9 is a diagram showing an example of a second proof image when it is inputted;

FIG. 10 is a diagram showing an example of different portions between the first proof image and the second proof image;

FIG. 11 is a diagram showing an example of the second proof image after being subjected to an automatic trap processing;

FIG. 12 is a diagram showing an example of the second proof image to which a trap edit history has been applied;

FIG. 13 is a diagram showing an example of the second proof image on which different portions are displayed; and

FIG. 14 is a diagram showing an example of the second proof image after a trap edit processing.

### DESCRIPTION OF THE PREFERRED EMBODIMENTS

Preferred embodiments of the present invention will be described below with reference to the accompanying drawings.

### 1. CONFIGURATION OF IMAGE PROCESSING APPARATUS

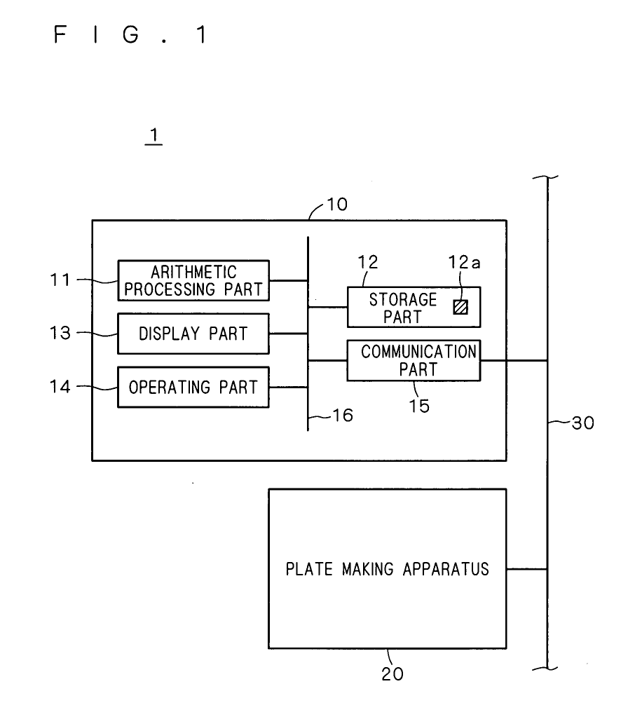

FIG. 1 is a block diagram showing the configuration of a plate making system 1 including an image processing apparatus 10 according to a preferred embodiment of the present invention. The plate making system 1 consists mainly of the image processing apparatus 10 and a plate making system 20, and these apparatuses are connected over a LAN 30. The image processing apparatus 10 is composed of a general computer provided with an arithmetic processing part 11, a storage part 12, a display part 13, an operating part 14, and a communication part 15. These components are electrically connected via a bus line 16, so that they can mutually perform sending and receiving of data.

The arithmetic processing part 11 is composed of a CPU or an MPU, and executes an image processing by performing a predetermined arithmetic processing based on a program 12a stored in the storage part 12, and an instruction inputted through the operating part 14. Specifically, the arithmetic processing part 11 executes various processing to be described later, such as image compare check, automatic trap processing, trap edit processing, preserving of a trap edit history, specification of a portion to which a trap edit history is applied, application of a trap edit history, and an RIP processing. The storage part 12 is made up of a ROM, a RAM, a hard disk, and the like, and stores various data necessary for an image processing. The storage part 12 also stores the program 12a necessary for the arithmetic processing part 11 to execute the image processing.

The display part 13 is made up of display devices such as a liquid crystal display and a CRT, and displays images and a variety of information to the operator. Especially, in step S27 to be described later, the display part 13 displays a different portion between the first proof image and the second proof image. The operating part 14 is made up of a keyboard, a mouse, and the like, and accepts an operation input from the operator. Especially, when performing a trap edit processing, the operating part 14 accepts the edit operation from the operator, and sends the edit contents thereof to the arithmetic processing part 11. The communication part 15 has an interface function for connecting the image processing apparatus 10 to the LAN 30. For example, the image transmitted over the LAN 30 is inputted via the communication part 15 to the image processing apparatus 10. The image subjected to the image processing in the image processing apparatus 10 is then outputted via the communication part 15 to the LAN 30.

The plate making apparatus 20 records the image after being subjected to the image processing, in a printing plate for each color component, and makes a plurality of printing plates used in a multicolor printing. For example, the plate making apparatus 20 is made up of a drum rotating in a horizontal scanning direction while holding a printing plate, and a recording head shifting in a vertical scanning direction while emitting a laser beam to the printing plate.

### 2. FLOW OF IMAGE PROCESSING

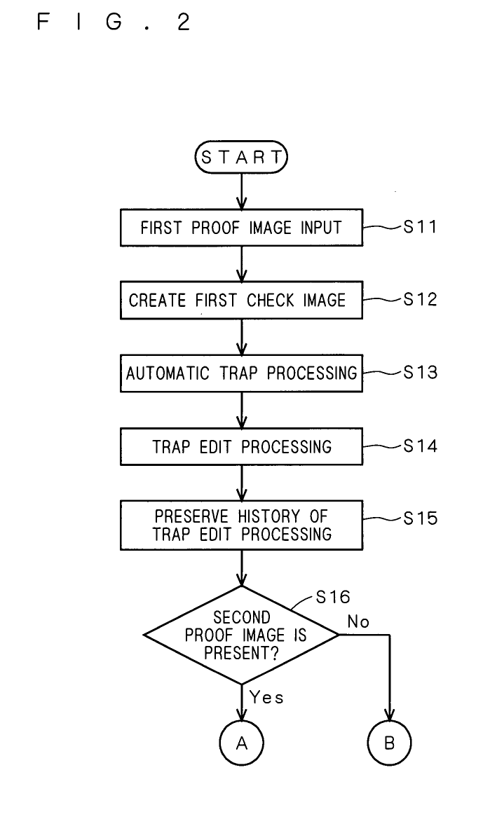

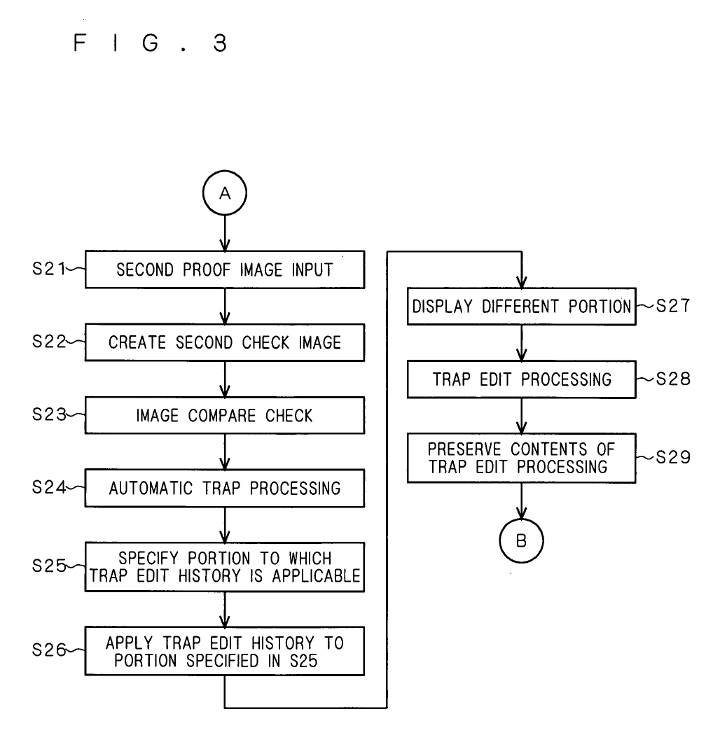

An image processing performed in the above-mentioned image processing apparatus 10 will next be described with reference to the flow charts of FIGS. 2 to 4. The image to be processed in the following image processing is an image for a multicolor printing where a plurality of objects (figures) are arranged, which is inputted to the plate making system 1 as a PDL (page-description language) described in the format of Portable Document Format, PostScript (registered trademark), or the like.

When a first proof image (namely an image initially made for a certain multicolor printed matter) is inputted to the plate making system 1, the inputted first proof image is transmitted over the LAN 30 and inputted via the communication part 15 to the image processing apparatus 10 (step S11). The image processing apparatus 10 checks whether or not the contents of descriptions in the format and header of the first proof image are suitable for the succeeding image processing. If the image processing apparatus 10 decided they are not suited for the image processing, it rejects the input of the first proof image, and displays the result on the display part 13. If decided they are suited for the image processing, it accepts the input of the first proof image.

On completion of the input of the first proof image, the image processing apparatus 10 creates a first check image based on the inputted first proof image (step S12). The first check image is bit map data to be created by the RIP processing to the first proof image, and each pixel of the first check image can be expressed by a multi-value. Preferably, the first check image is created in the minimum size, for example, at a resolution of about 100 to 600 dpi., at which any different portion is detectable in an image compare check to be described later. The created first check image is then stored in the storage part 12, for use in step S23 to be described later.

Subsequently, the image processing apparatus 10 performs an automatic trap processing to the first proof image (step S13). In the automatic trap processing, boundary figures for filling the boundary portions of the respective colors existing in the first proof image are created uniformly based on predetermined parameters (shape, width, color, and direction to place), and the created boundary figures are placed at the respective corresponding boundary portions. The first proof image after being subjected to the automatic trap processing is then displayed on the display part 13.

The operator checks the first proof image after subjected to the automatic trap processing displayed on the display part 13, and performs a trap edit processing as needed (step S14). The operator operates the operating part 14 to correct individually the parameters of the boundary figure related to the portion to which the optimum trap processing is not applied. The image processing apparatus 10 accepts the edit processing executed by the operator, which is inputted through the operating part 14, and corrects the data as per the instruction. Thus, the trap processing to the first proof image can be optimized in appearance.

At the termination of the trap edit processing, the image processing apparatus 10 preserves, as a history, the contents of the above-mentioned trap edit processing in the storage part 12 (step S15). That is, the image processing apparatus 10 preserves in the storage part 12 the parameters of the respective boundary figures corrected in the trap edit processing. This can be executed, for example, by the operation that the operator clicks a predetermined icon displayed on the display part 13.

Thereafter, the image processing apparatus 10 checks whether or not a second proof image (the image to which a partial change has been added to the first proof image) is already inputted in the plate making system 1 (step S 16). If the second proof image is already inputted, the apparatus 10 moves the procedure to step S21, and starts the processing to the second proof image. On the other hand, if not yet inputted, it moves the procedure to step S31, and performs a RIP processing and an output processing. In this check processing, the image processing apparatus 10 may automatically recognize the data on the LAN 30, or the operator may operate to input the result of the check into the image processing apparatus 10.

When the second proof image is inputted, the second proof image transmitted over the LAN 30 is then inputted via the communication part 15 to the image processing apparatus 10 (step S21). The image processing apparatus 10 checks in the same manner as in the first proof image, as to whether or not the contents of the format and header of the second proof image are suitable for the succeeding image processing. If the image processing apparatus 10 decided they are not suited for the image processing, it rejects the input of the second proof image, and displays the result on the display part 13. If decided they are suited for the image processing, it accepts the input of the second proof image.

On completion of the input of the second proof image, the image processing apparatus 10 creates a second check image based on the inputted second proof image (step S22). The second check image is bit map data to be created by the RIP processing to the second proof image, and each pixel of the first check image can be expressed by a multi-value. Preferably, the second check image is created in the minimum size, for example, at a resolution of about 100 to 600 dpi., at which any different portion is detectable in the image compare check to be described later. For the compare check to be described later, the resolution of the created second check image matches with that of the first check image. The created second check image is then preserved together with the above-mentioned first check image in the storage part 12.

Thereafter, the image processing apparatus 10 reads the first check image and the second check image stored in the storage part 12, and performs a compare check of the two images (step S23). That is, the apparatus 10 compares the two images pixel by pixel, and extracts the pixel having such a difference in pixel value as to exceed the allowable value, as a different pixel. Based on the different pixels so extracted from the first and second check images, the image processing apparatus 10 specifies a different portion between the first and second proof images. Thus, the portion changed in the second proof image can be distinguished. Information of the different portion between the first and second proof images is then preserved temporarily in the storage part 12. In this image compare check processing, if the resolution of the first check image does not match the resolution of the second check image, it is desirable to perform such a resolution change processing as to change the resolution of either one to the resolution of the other.

The image processing apparatus 10 also performs an automatic trap processing to the second proof image (step S24). In the automatic trap processing, boundary figures for filling the boundary portions of the respective colors existing in the second proof image are created uniformly based on the same parameters as in the first proof image (shape, width, color, and direction to place), and the created boundary figures are placed at the respective corresponding boundary portions. The second proof image after being subjected to the automatic trap processing is then displayed on the display part 13.

Next, the image processing apparatus 10 refers to the history of the trap edit processing preserved in the storage part 12 in step S15, and to the information of the different portions preserved in the storage part 12 in step S23. Based on these, the image processing apparatus 10 specifies portions where the trap edit processing to the first proof image is performed, and where the first proof image and the second proof image are common to each other. The portions so specified are distinguished as portions to which the history of the trap edit processing to the first proof image can be applied directly (step S25).

Thereafter, with respect to the portion so specified in step S25, the image processing apparatus 10 applies the history of the trap edit processing to the first proof image to the second proof image (step S26). Thus, with respect to the portions common to the first and second proof images, the trap edit processing to the first proof image can be reproduced automatically. Consequently, there is no necessity for the operator to check and perform the trap edit processing one by one in the common portions, thereby improving the efficiency of the trap edit processing to the second proof image. Further, the trap edit processing to the first proof image can be executed surely to the second proof image.

The image processing apparatus 10 also reads the different portions preserved in the storage part 12 in step S23, and displays it on the display part 13 (step S27). For example, the image processing apparatus 10 creates a marking image indicating the different portions, and overlaps and displays them on the second proof image displayed on the display part 13. The operator can recognize easily the portions changed in the second proof image by checking the different portions displayed on the display part 13.

Hence, the operator checks only the different portions in the second proof image displayed on the display part 13, and performs the trap edit processing as needed (step S28). The operator selects the different portions in sequence by pushing a predetermined key on the operating part 14, and individually corrects the parameters of the boundary figures in respect to the portion not subjected to the optimum trap processing. The image processing apparatus 10 accepts the edit processing inputted through the operating part 14, and corrects the data as per instruction. Thus, the trap processing to the second proof image can be optimized in appearance.

On completion of the trap edit processing, the image processing apparatus 10 preserves, as a history, the contents of the trap edit processing applied in step S26, and the contents of the trap edit processing performed in step S28, in the storage part 12 (step S29). With this configuration, for example, when a third proof image is inputted, the preserved histories can be read and used as needed.

Thereafter, the image processing apparatus 10 performs an RIP processing to the second proof image after subjected to the trap edit processing (step S31). In the RIP processing, the second proof image is converted to a multi-gradation image and further converted to a dot image. Then, the image processing apparatus 10 outputs the created dot image through the communication part 15 and transmits it to the plate making apparatus 20 over the LAN 30 (step S32). Similarly, if decided the second proof image is not yet inputted in step S16, the RIP processing is to be performed to the first proof image, and the created dot image is to be outputted to the plate making apparatus 20.

As described above, the image processing apparatus 10 of the present embodiment compares the first proof image and the second proof image to detect different portions therebetween, and displays the different portions on the display part 13. Therefore, the operator can check the second proof image after subjected to the automatic trap processing, only in respect to the different portions between the first and second proof images, and perform the trap edit processing as needed. This enables an efficient trap edit processing to the second proof image, and also reduces the operator's workload.

The image processing apparatus 10 creates the first check image and the second check image based on the inputted first proof image and the second proof images, respectively, and detects the different portions based on the first and second check images. It is therefore capable of appropriately detecting the different portions based on the images suitable for the compare check processing.

Further, the image processing apparatus 10 preserves the contents of the trap edit processing to the first proof image in the storage part 12, and applies the preserved contents to the second proof image. This further reduces the operator's workload in the trap edit processing to the second proof image. The trap edit processing to the first proof image can also be surely performed to the second proof image.

Furthermore, the image processing apparatus 10 specifies portions where the trap edit processing to the first proof image if performed, and where the first and second proof images are common to each other. It is therefore capable of distinguishing portions to which the history of the trap edit processing to the first proof image can be applied directly to the second proof image.

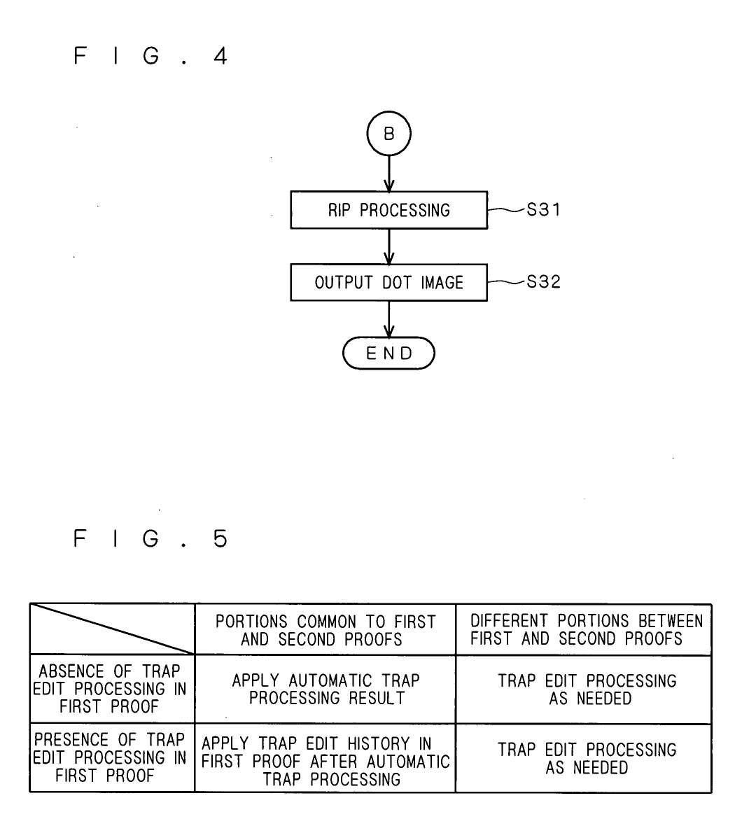

The processing to the second proof image to be performed after the automatic trap processing in the image processing apparatus 10 can be summarized as in FIG. 5. That is, the results of the automatic trap processing is applied to the portions of the second proof image where the trap edit processing to the first proof image is not performed, and where are common to the first proof image and the second proof image. The trap edit history of the first proof image is applied to the portions of the second proof image where the trap edit processing to the first proof image is performed, and where are common to the first proof image and the second proof image. The operator visually checks the portion of the second proof image which is different from the first proof image, and performs a trap edit processing as needed. Hence, the trap edit processing to the second proof image can be performed very efficiently.

### 3. EXAMPLES

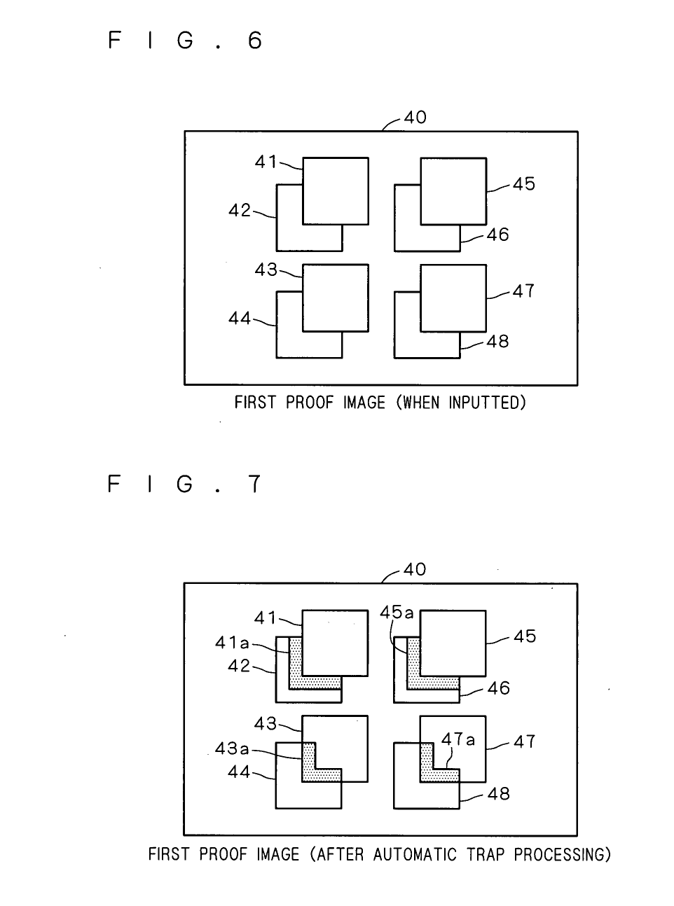

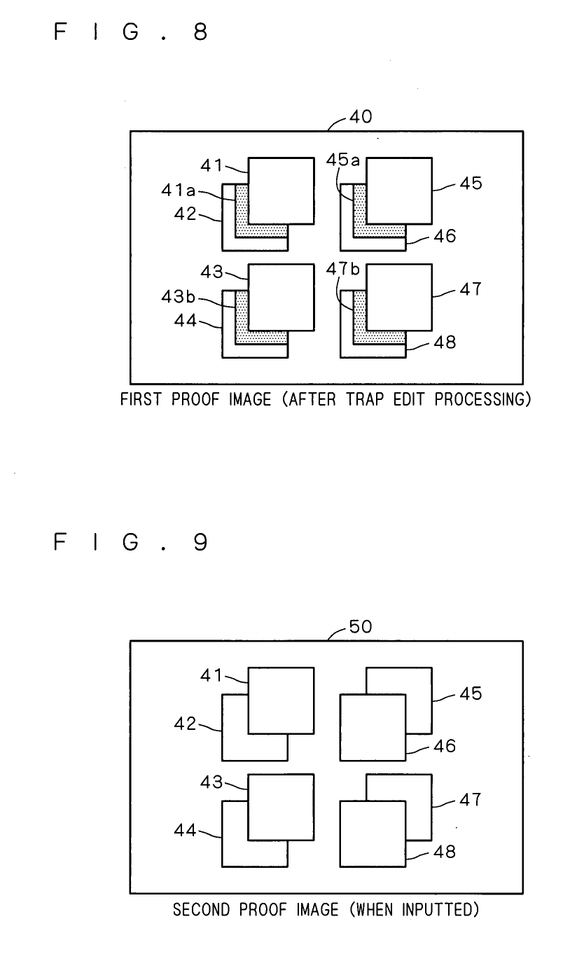

The above-mentioned image processing will be further described with reference to the examples of images. FIG. 6 is a diagram showing an example of a first proof image inputted to the image processing apparatus 10. A first proof image 40 of FIG. 6 is an image where eight rectangular objects 41 to 48 having different colors are arranged. There are partial overlaps between the objects 41 and 42, between the objects 43 and 44, between the objects 45 and 46, and between the objects 47 and 48, respectively. It is assumed that after the automatic trap processing to the first proof image 40, boundary FIGS. 41a, 43a, 45a, and 47a are created and placed as shown in FIG. 7. The operator checks the first proof image 40 after subjected to the automatic trap processing, and if decided that the boundary FIGS. 43a and 47a should be corrected, the operator corrects individually the parameters of the boundary FIGS. 43a and 47a. As the result, boundary FIGS. 43b and 47b are created to place on the first proof image 40, as shown in FIG. 8.

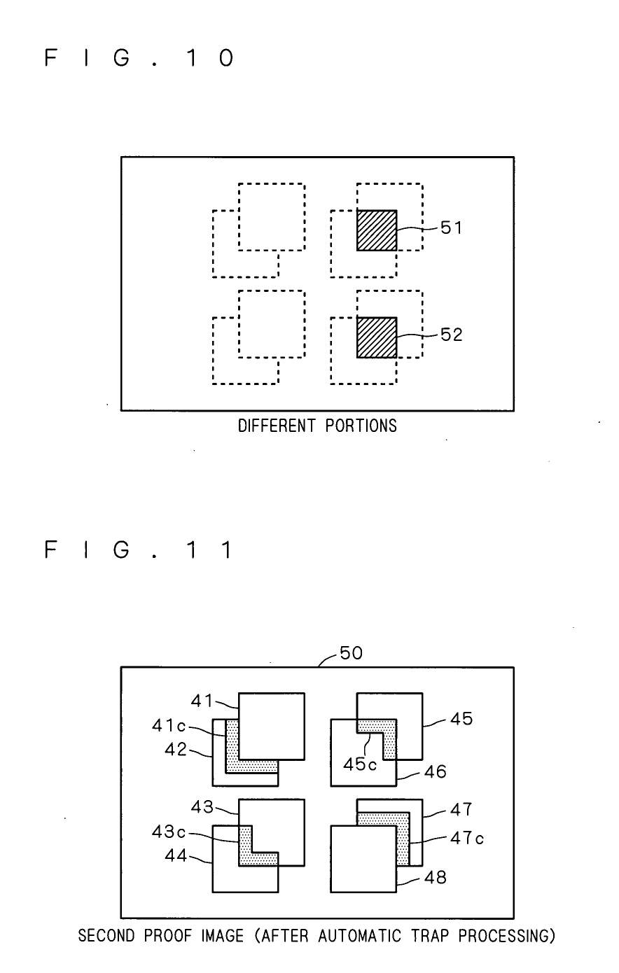

On the other hand, it is assumed that a second proof image 50 as shown in FIG. 9 is inputted to the image processing apparatus 10. The second proof image 50 can be obtained by changing the first proof image 40 so that the object 46 is displayed at an upper position than the object 45, and the object 48 is displayed at an upper position than the object 47. A compare check processing to the first proof image 40 and the second proof image 50 specifies different portions 51 and 52 between the first and second proof images 40 and 50, as shown in FIG. 10.

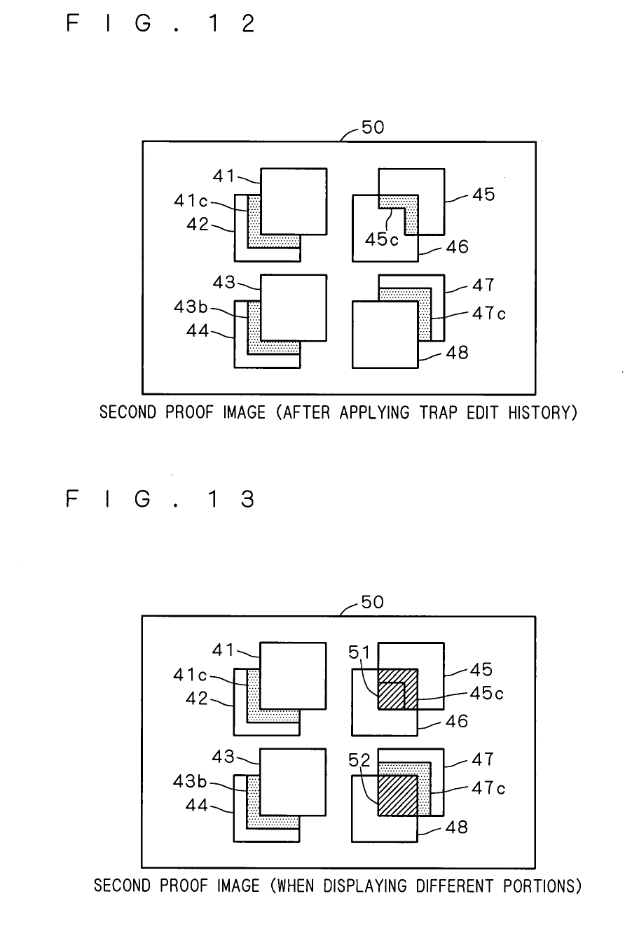

It is assumed that after the automatic trap processing to the second proof image 50, boundary FIGS. 41c, 43c, 45c, and 47c are placed as shown in FIG. 11. With respect to the boundary portion between the objects 43 and 44, the trap edit processing is performed to the first proof image 40, and the first proof image 40 is common to the second proof image 50. Therefore, the history of the trap edit processing to the first proof image 40 can be applied to the boundary portion between the objects 43 and 44. Thus, the boundary FIG. 43c can be corrected to place the boundary FIG. 43b, as shown in FIG. 12.

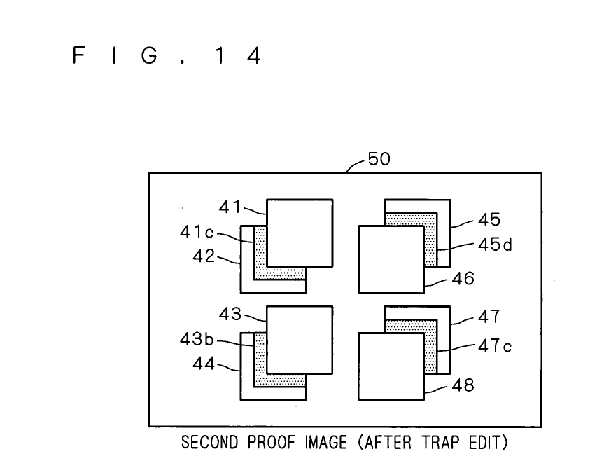

Further, as shown in FIG. 13, different portions 51 and 52 between the first proof image 40 and the second proof image 50 are highlighted. The operator individually checks the highlighted different portions 51 and 52, and if decided that the boundary FIG. 45c should be corrected, corrects individually the parameters of the boundary FIG. 45c. As the result, a boundary FIG. 45d can be created to place on the second proof image 50, as shown in FIG. 14.

Thus in the present example, the different portions 51 and 52 between the first proof image 40 and the second proof image 50 can be specified, and the different portions 51 and 52 can be highlighted on the second proof image 50. When performing the trap edit processing to the second proof image 50, the operator performs the trap edit processing by checking only the different portions 51 and 52. The history of the trap edit processing to the second proof image 40 can be applied to the boundary portion between the objects 43 and 44. It is therefore capable of efficiently performing the trap edit processing to the second proof image, and reducing the operator's workload.

### 4. MODIFICATION

While the preferred embodiment of the present invention has been described above, the present invention is not limited to this. For example, though in the foregoing embodiment, the check images are created by the RIP processing, other image conversion processing may be used to create the check images. Alternatively, without creating any check images, the contents of description of the first proof image and that of the second proof image may be compared directly. Nevertheless, when the RIP processing is used to create the check images, only the different portions in appearance can be detected efficiently by comparing only the portions that appear in appearance on the image.

Although in the foregoing embodiment, the check images having a relatively small size are created by the RIP processing, an intermediate image having a relatively large size may be formed by the RIP processing, and the intermediate image may be then reduced to create a check image. By so doing, fine figures contained in the image can be surely expressed on the check image, thus leading to more excellent image compare check.

While the invention has been shown and described in detail, the foregoing description is in all aspects illustrative and not restrictive. It is therefore understood that numerous modifications and variations can be devised without departing from the scope of the invention.

What is claimed is:

1. An image processing apparatus performing an image processing including a trap processing in respect to an image for a multicolor printing, said image processing apparatus comprising:
an image input part to input an image;
an automatic trap processing part to perform an automatic trap processing based on a predetermined condition, in respect to an inputted image;
a trap edit processing accepting part to accept a trap edit processing in which an image after being subjected to said automatic trap processing is individually corrected by an operator;
a compare check part to compare and detect, when a first proof image and a second proof image are inputted to said image input part, a different portion between said first proof image and said second proof image; and
a display part to display said different portion,
wherein said trap edit processing accepting part accepts a trap edit processing to said second proof image in respect to said different portion displayed on said display part.

2. The image processing apparatus according to claim 1, further comprising:
a check image creating part to create a check image based on an inputted image,
wherein said compare check part compares a first check image created based on said first proof image and a second check image created based on said second proof image, to detect a different portion.

3. The image processing apparatus according to claim 2, further comprising:
a preserving part to preserve contents of said trap edit processing.

4. The image processing apparatus according to claim 3, further comprising:
an applying part to apply said contents of said trap edit processing to said first proof image which is preserved by said preserving part, to said second proof image.

5. The image processing apparatus according to claim 4, further comprising:
a specifying part to specify a portion where said trap edit processing to said first proof image is performed, and where said first proof image and said second proof image are common to each other.

6. An image processing method of performing an image processing including a trap processing with respect to an image for a multicolor printing, comprising the steps of:
(a) inputting an image;
(b) performing an automatic trap processing based on a predetermined condition, in respect to an input image;
(c) performing a trap edit processing to an image after subjected to an automatic trap processing; and
(d) when a second proof image is inputted after a first proof image in said step (a), comparing said first proof image and said second proof image to detect a different portion,
wherein in said step (c), a trap edit processing to said second proof image is performed in respect to said different portion.

7. The image processing method according to claim 6, further comprising the step of:
(e) displaying said different portion detected in said step (d).

8. The image processing method according to claim 7, further comprising the step of:
(f) creating a check image based on an image inputted in said step (a).
wherein in said step (d), a first check image created based on said first proof image and a second check image created based on said second proof image are compared to detect a different portion.

9. The image processing method according to claim 8, further comprising the step of:
(g) preserving contents of said trap edit processing in said step (c).

10. The image processing method according to claim 9, further comprising the step of:
(h) applying said contents of said trap edit processing to said first proof image which is preserved in said step (g), to said second proof image.

11. The image processing method according to claim 10, further comprising the step of:
(i) specifying a portion where said trap edit processing to said first proof image is performed, and where said first proof image and said second proof image are common to each other.

12. A program stored in a storage medium to be executed by a computer so as to implement the following functions:
(a) inputting an image;
(b) performing an automatic trap processing based on a predetermined condition, in respect to an input image;
(c) performing a trap edit processing to an image after subjected to an automatic trap processing; and
(d) when a second proof image is inputted after a first proof image in said function (a), comparing said first proof image and said second proof image to detect a different portion,
wherein in said function (c), a trap edit processing to said second proof image is performed in respect to said different portion.

13. The program stored in a storage medium according to claim 12, further comprising the function:
(e) displaying said different portion detected by said function (d).

14. The program stored in a storage medium according to claim 13, further comprising the function of:
(f) creating a check image based on an image inputted by said function (a),
wherein in said function (d), a first check image created based on said first proof image and a second check image created based on said second proof image are compared to detect a different portion.

15. The program stored in a storage medium according to claim 14, further comprising the function of:
(g) preserving contents of said trap edit processing by said function (c).

16. The program stored in a storage medium according to claim 15, further comprising the function of:
(h) applying said contents of said trap edit processing to said first proof image which is preserved in said function (g), to said second proof image.

17. The program stored in a storage medium according to claim 16, further comprising the function of:
(i) specifying a portion where said trap edit processing to said first proof image is performed, and where said first proof image and said second proof image are common to each other.
